(19) United States
(12) Patent Application Publication
(10) Pub. No.: US 2002/0149023 A1
(43) Pub. Date: Oct. 17, 2002

(54) Structure and method for fabricating III-V nitride devices utilizing the formation of a compliant substrate

(75) Inventors: Lyndee L. Hilt, Chandler, AZ (US); Jamal Ramdani, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 10/161,743

(22) Filed: Jun. 5, 2002

Related U.S. Application Data
(63) Continuation of application No. 09/753,808, filed on Jan. 3, 2001, now abandoned.

(51) Int. Cl. H01L 31/12

(52) U.S. Cl. 257/79

(57) ABSTRACT

High quality epitaxial layers of monocrystalline materials can be grown overlying large silicon wafers by first growing an accommodating buffer layer (202) on a silicon substrate (200). The accommodating buffer layer (202) is a layer of monocrystalline material spaced apart from the silicon substrate (200) by an amorphous interface layer (204) of silicon oxide. The amorphous interface layer dissipates strain and permits the growth of a high quality monocrystalline accommodating buffer layer. Any lattice mismatch between the accommodating buffer layer and the underlying silicon substrate is taken care of by the amorphous interface layer. Utilizing this technique permits the fabrication of semiconductor structures formed by high quality Group III-V nitride films.

### FIELD OF THE INVENTION

This invention relates generally to semiconductor structures and devices and to a method for their fabrication, and more specifically to fabrication of semiconductor structures formed of Group III-V nitride films on compliant substrates using epitaxial lateral overgrowth processing.

### BACKGROUND OF THE INVENTION

Semiconductor devices typically include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric-films improves as the crystallinity of these layers increases.

For many years, attempts have been made to grow various monolithic thin films on a foreign substrate, such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure.

This structure and process could have extensive applications. One such application of this structure and process involves the fabrication of electrical and optical devices from Group III-V nitride materials. Group III-V nitrides, such as GaN, InN and the like, have large, direct bandgaps, structural stability and high thermal stability which makes them suitable for a wide range of electrical and optical device applications such as high power LEDs.

One significant challenge to large scale production of III-V nitride devices is the lack of bulk substrates formed of suitable lattice-matched material for subsequent high quality epitaxial III-V nitride growth. Currently, III-V nitride growth is carried out on sapphire which has a lattice constant and thermal conductivity significantly different from the III-V nitrides. These significant differences lead to mechanical stresses in the subsequent film growth above the critical thickness, which result in cracking. To increase the III-V nitride film thickness without cracking, a buffer layer of ZnO or AIN is often deposited on the sapphire before deposition of the III-V nitride material. The buffer layer reduces the III-V nitride film cracking but does not address further improvements in the electrical and structural quality of the thicker epitaxial layers. Another disadvantage of typical III-V nitride materials is the high number of defect dislocations in the material layers. These defects impact the electrical and optical performance of the III-V nitride devices. For example, in optical devices, the defects act as scattering centers requiring a higher laser threshold current density. In electrical devices, dislocations can create deep defect energy levels that increase the leakage current.

One current method that has shown a reduction in dislocation density is selective epitaxial lateral overgrowth (“ELO”) on patterned substrates. While ELO can relieve the stress caused by the lattice mismatch and differences in thermal expansion coefficients between sapphire and III-V nitrides, the defect density in the III-V nitride layers is still significant enough to adversely impact performance of devices made therefrom.

Accordingly, a need exists for a semiconductor structure that provides high quality electrical and optical devices formed of Group III-V nitride materials and for a process for making such a structure.

### BRIEF DESCRIPTION OF THE DRAWINGS

The present invention is illustrated by way of example and not limitation in the accompanying figures, in which like references indicate similar elements, and in which:

FIGS. 1 and 2 illustrate schematically, in cross section, device structures in accordance with various embodiments of the invention;

FIG. 3 illustrates graphically the relationship between maximum attainable film thickness and lattice mismatch between a host crystal and a grown crystalline overlayer;

FIG. 4 illustrates a high resolution Transmission Election Micrograph of a structure including a monocrystalline accommodating buffer layer;

FIG. 5 illustrates an x-ray diffraction spectrum of a structure including a monocrystalline accommodating buffer layer;

FIGS. 6A-6D illustrate schematically, in cross-section, the formation of a device structure in accordance with another embodiment of the invention;

FIGS. 7A-7D illustrate a probable molecular bonding structure of the device structures illustrated in FIGS. 6A-6D.

FIGS. 8-10 illustrate schematically, in cross-section, the formation of yet another embodiment of a device structure in accordance with the invention;

FIGS. 11-14 illustrate schematically, in cross-section, the formation of an exemplary embodiment of a semiconductor structure fabricated on a semiconductor substrate according to the present invention;

FIGS. 15 and 16 illustrate schematically, in cross-section, the formation of another exemplary embodiment of a semiconductor structure fabricated on a semiconductor substrate according to the present invention; and

FIGS. 17-19 illustrate schematically, in cross-section, the formation of another exemplary embodiment of a semiconductor structure fabricated on a semiconductor substrate according to the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26, which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitride may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphede (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

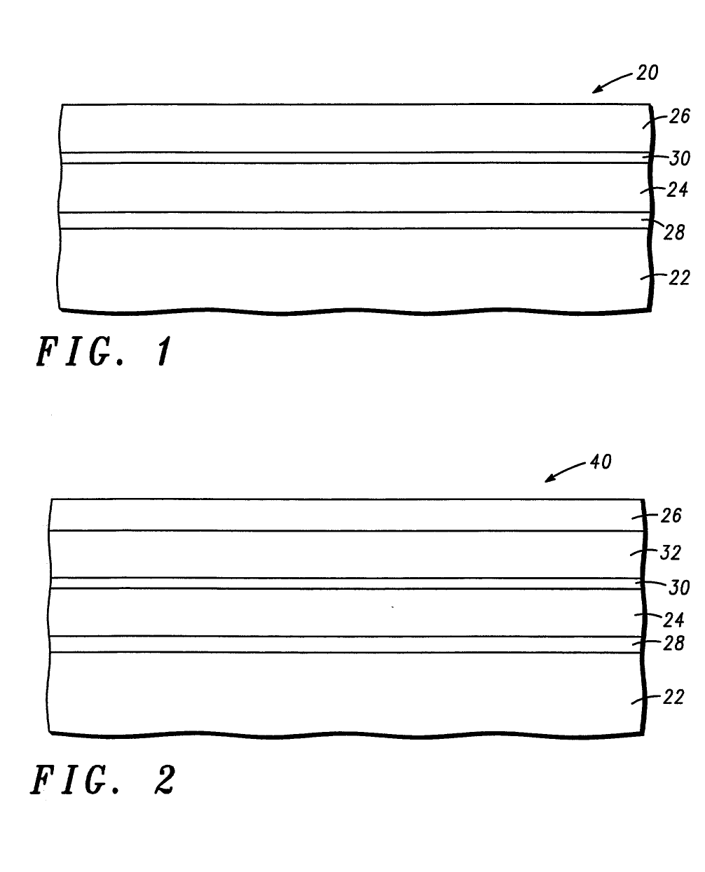

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

The following non-limiting, illustrative examples illustrate various combinations of materials useful in structures 20 and 40 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1-2 nm.

In accordance with the embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of preferred example, 1-2 monolayers of Ti—As or Sr—Ga—O have been shown to successfully grow GaAs layers.

### EXAMPLE 2

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

Referring again to FIGS. 1 and 2, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

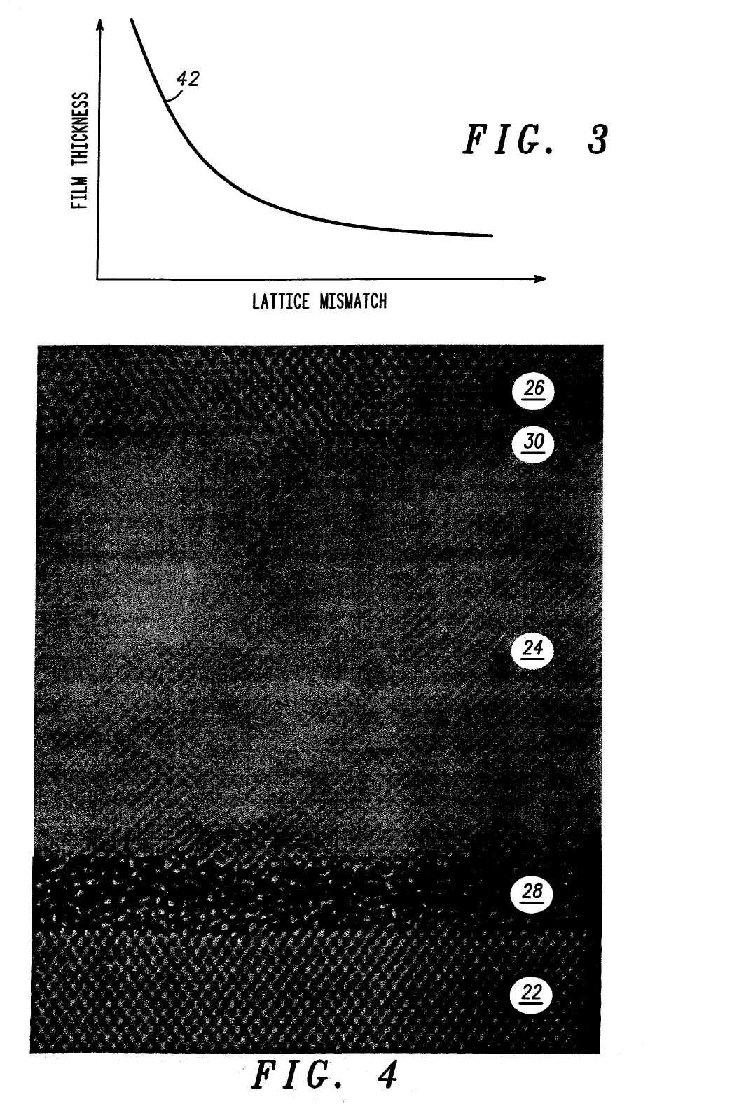

FIG. 3 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1 and 2, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1 and 2. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen, 1-2 monolayers of strontium, or with 1-2 monolayers of strontium-oxygen.

Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 4 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

FIG. 5 illustrates an x-ray diffraction spectrum taken on a structure including monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The buffer layer is formed overlying the template layer before the deposition of the monocrystalline material layer. If the buffer layer is a monocrystalline material layer comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

The process described above illustrates a process for forming a semiconductor structure including a silicon substrate, an overlying oxide layer, and a monocrystalline material layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising indium gallium arsenide, indium aluminum arsenide, or indium phosphide.

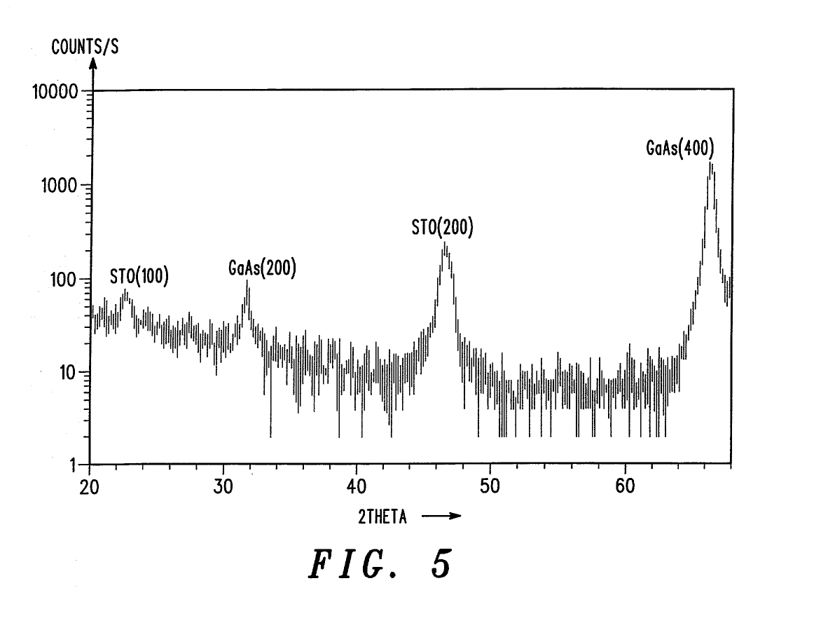

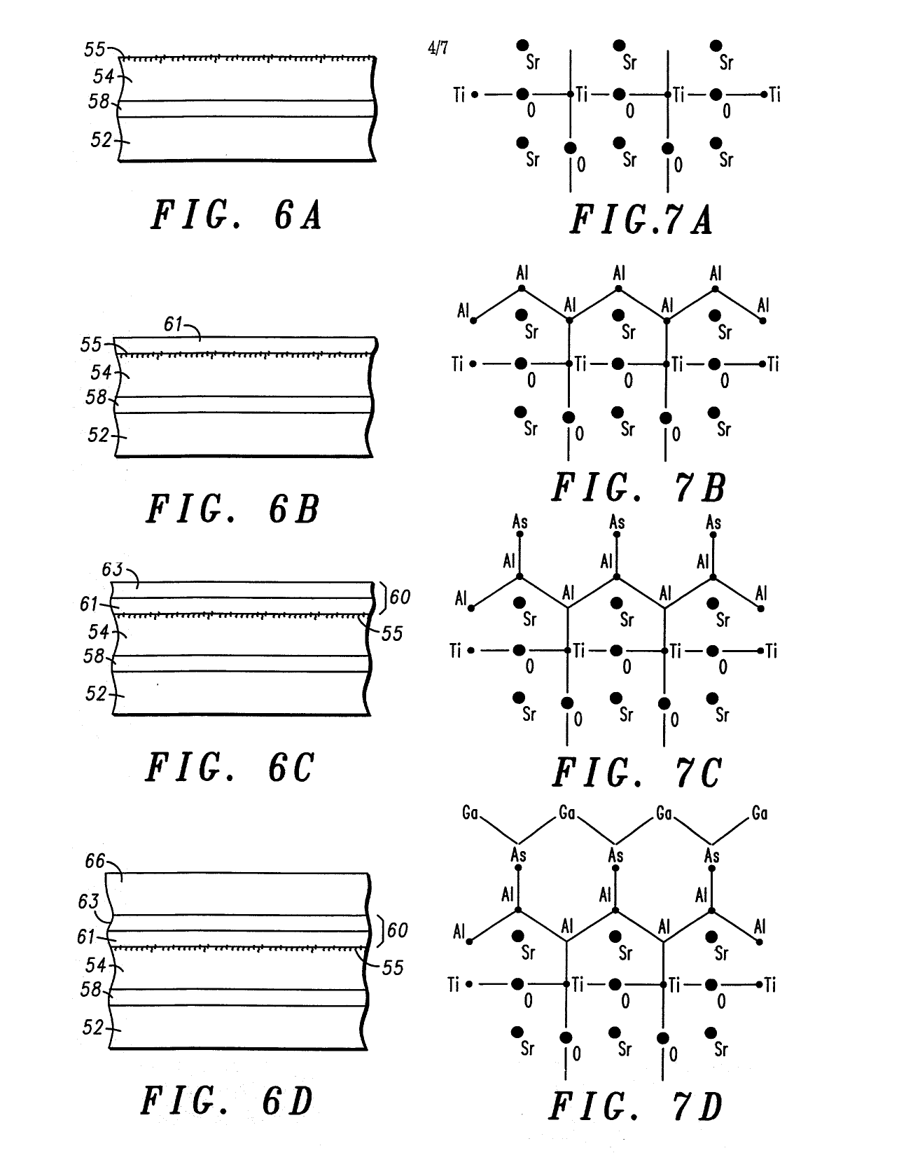

The formation of a device structure in accordance with another embodiment of the invention is illustrated schematically in cross-section in FIGS. 6A-6D. Like the previously described embodiments referred to in FIGS. 1 and 2, this embodiment of the invention involves the process of forming a compliant substrate utilizing the epitaxial growth of single crystal oxides, such as the formation of accommodating buffer layer 24 previously described with reference to FIGS. 1 and 2 and the formation of a template layer 30. However, the embodiment illustrated in FIGS. 6A-6D utilizes a template that includes a surfactant to facilitate layer-by-layer monocrystalline material growth.

Turning now to FIG. 6A, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2.

Layer 54 is grown with a strontium (Sr) terminated surface represented in FIG. 6A by hatched line 55 which is followed by the addition of a template layer 60 which includes a surfactant layer 61 and capping layer 63 as illustrated in FIGS. 6B and 6C. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 6B by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a halogen such as arsenic, for example, to form capping layer 63 as illustrated in FIG. 6C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 6D.

FIGS. 7A-7D illustrate possible molecular bond structures for a specific example of a compound semiconductor structure formed in accordance with the embodiment of the invention illustrated in FIGS. 6A-6D. More specifically, FIGS. 7A-7D illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 6B-6D, to increase the surface energy of the monocrystalline oxide layer 54 and also to shift the crystalline structure of the template to a diamond-like structure that is in compliance with the original GaAs layer.

FIG. 7A illustrates the molecular bond structure of a strontium terminated surface of a strontium titanate monocrystalline oxide layer. An aluminum surfactant layer is deposited on top of the strontium terminated surface and bonds with that surface as illustrated in FIG. 7B, which reacts to form a capping layer comprising a monolayer of Al₂Sr having the molecular bond structure illustrated in FIG. 7B which forms a diamond-like structure with an sp³ hybrid terminated surface that is compliant with compound semiconductors such as GaAs. The structure is then exposed to As to form a layer of AlAs as shown in FIG. 7C. GaAs is then deposited to complete the molecular bond structure illustrated in FIG. 7D which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising germanium (Ge), for example, to form high efficiency photocells.

FIGS. 8-10 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 8 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2 but preferably comprises a monocrystalline oxide material such as a monocrystalline layer of Sr_{z}Ba_{1-z}TiO₃ where z ranges from 0 to 1. Substrate 102 is preferably silicon but may also comprise any of those materials previously described with reference to substrate 22 in FIGS. 1 and 2.

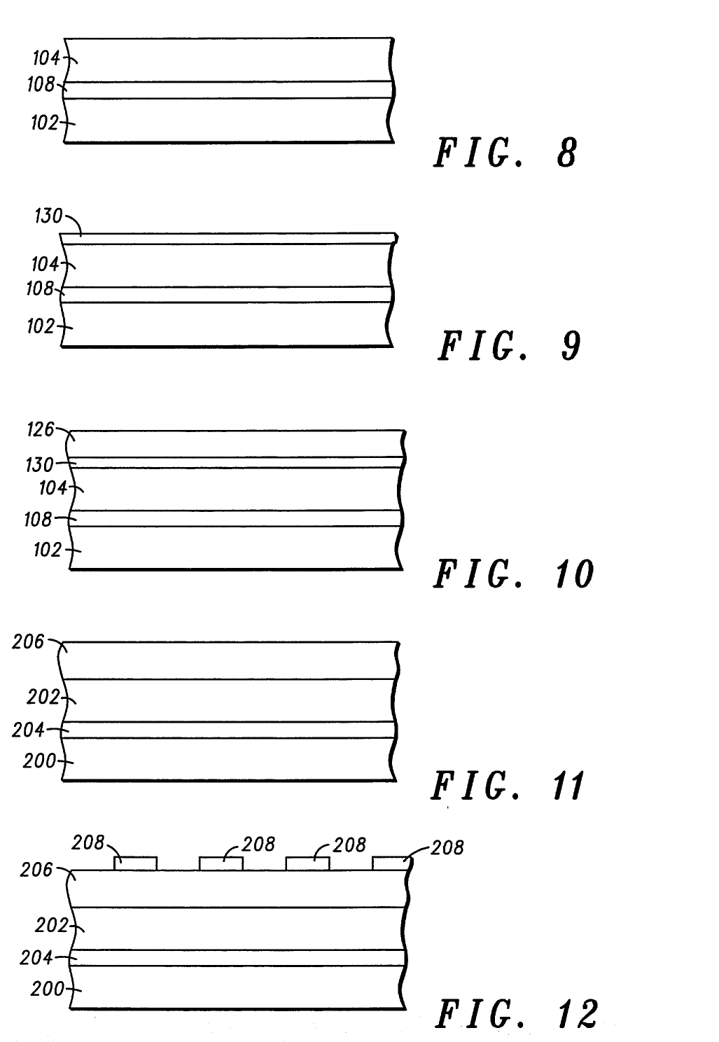

A template layer 130 is deposited over accommodating buffer layer 104 as illustrated in FIG. 9 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr_{z}, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 10. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{l-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

The formation of a device structure formed of Group III-V nitride material in accordance with another embodiment of the invention is illustrated schematically in cross-section in FIGS. 11-14. Like the previously described embodiments referred to in FIGS. 1 and 2, this embodiment of the invention involves the process of forming a compliant substrate utilizing the epitaxial growth of single crystal oxides.

Turning now to FIG. 11, to fabricate a Group III-V nitride structure, a monocrystalline substrate 200 such as silicon (100) functions as the starting material. An accommodating buffer layer 202 is then grown epitaxially over substrate 200 and an amorphous intermediate layer 204 may be formed between substrate 200 and buffer layer 202 by the oxidation of substrate 200 during the growth of buffer layer 202. Buffer layer 202 may be comprised of a monocrystalline oxide or nitride material such as that comprising layer 24, 54 and 104 with reference to FIGS. 1, 6, and 8, respectively. Preferably, buffer layer 202 is comprised of SrTiO₃ epitaxially grown on substrate 200. In accordance with one embodiment of the invention (not illustrated), a layer may comprise material from amorphous oxide layer 204 and material from layer 202, which is formed by annealing amorphous intermediate layer 204 and buffer layer 202, forming a layer such as layer 36 described with reference to FIG. 3. A monocrystalline material layer 206 is then epitaxially deposited over buffer layer 202. Monocrystalline material layer 206 may be comprised of a monocrystalline material such as that comprising layer 26 with reference to FIGS. 1 and 2, layer 66 with reference to FIG. 6D and layer 126 with reference to FIG. 10, but is preferably GaAs or Si. The structure illustrated in FIG. 11 is similar to structure 20 of FIG. 1, except that a template layer is not shown in FIG. 11. Nevertheless, the structure in FIG. 11 may include a template layer between any adjacent monocrystalline layers as described herein.

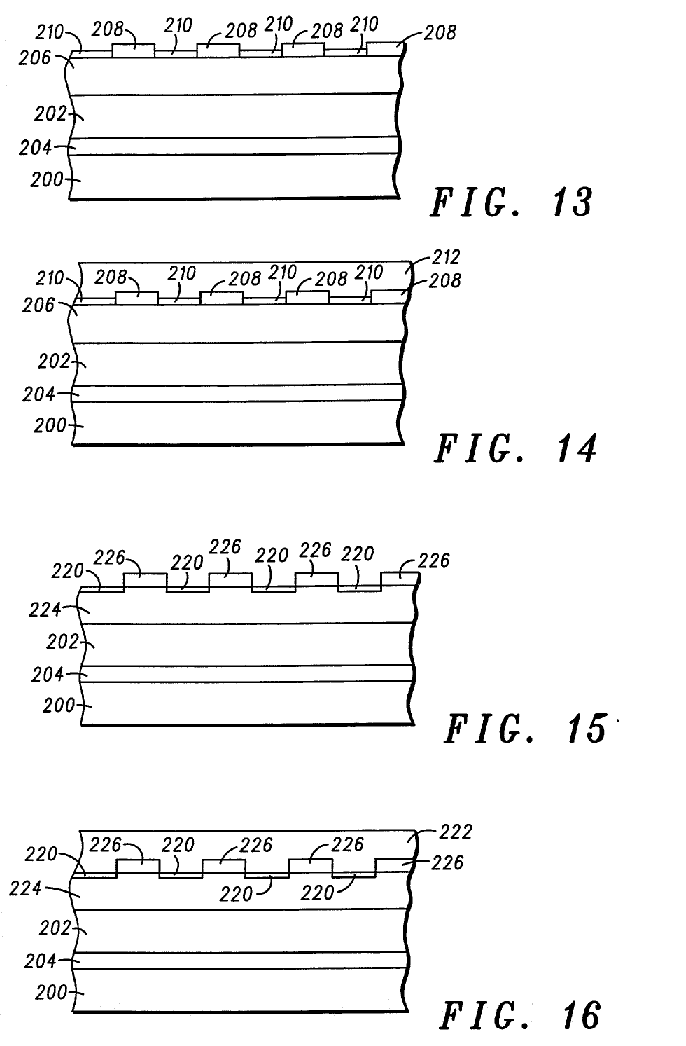

Referring to FIG. 12, a dielectric material is then lithographically deposited on monocrystalline material layer 206 to form patterned features 208 for subsequent epitaxial lateral overgrowth (“ELO”) processing. Patterned features 208 may be comprised of any suitable dielectric material but is preferably comprised of SiO₂ or SiNₓ. Turning to FIG. 13, ELO processing is then used to grow III-V nitride films having a reduced number of defects compared to conventional III-V nitride films. A layer 210 of Si, preferably with a thickness of several monolayers, is deposited with growth conditions that cause the Si to migrate from the patterned features 208 into wells between patterned features 208. Carbonization is then conducted to carbonize layer 210 to convert it to SiC.

Referring to FIG. 14, a III-V nitride film 212 is then epitaxially grown over patterned features 208 and SiC layer 210. Film 212 grows vertically to fill the wells between patterned features 208 and then grows laterally over patterned features 208. With this growth process, defect density is reduced, as vertical-through dislocations do not propagate in the lateral direction, thereby creating a film that is smooth and uniform.

Another device structure formed of Group III-V nitride material may be formed in accordance with an alternative embodiment of the invention. In this alternative embodiment, the above steps described with reference to FIGS. 11 and 12 are performed to create amorphous intermediate layer 204, accommodation buffer layer 202 and monocrystalline material layer 224 formed of GaAs, as illustrated in FIG. 15. As described above with reference to FIG. 12, patterned features 226 are then lithographically grown on the GaAs layer 224. The exposed portions of layer 224 between patterned features 226 are then subjected to nitridation to create GaN seed layers 220, preferably with a thickness of 1-10 nm, at the surface of GaAs layer 224. Alternatively, GaN seed layers 220 may be formed by depositing a layer of GaAs (not shown) after formation of patterned features 226. The GaAs layer, preferably with a thickness of several monolayers, is deposited with growth conditions that cause the GaAs to migrate from the patterned features 226 into the wells between patterned features 226. The GaAs layer is then subjected to nitridation to create GaN seed layers.

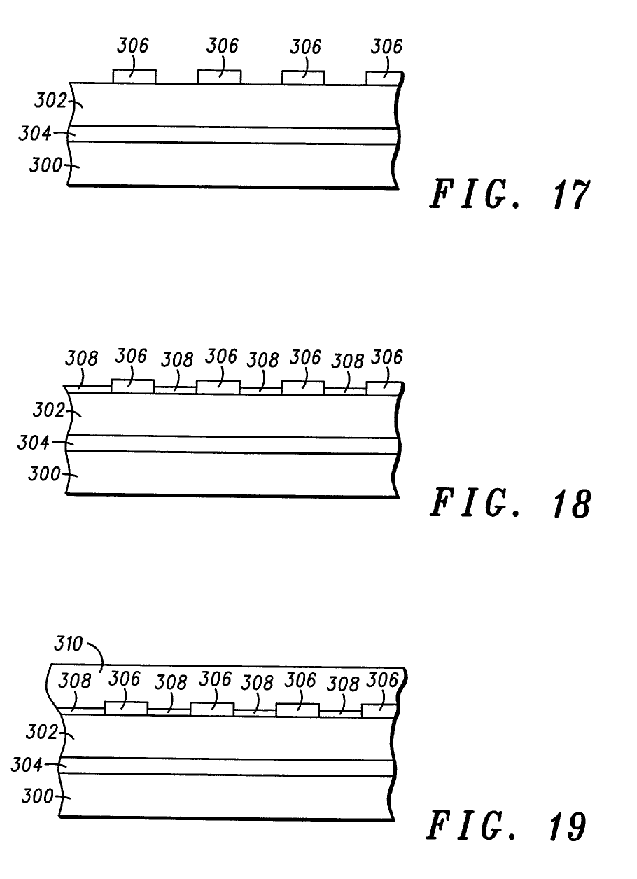

Referring to FIG. 16, a III-V nitride film 222 is then epitaxially grown over patterned features 226 and GaN seed layers 220 using ELO processing, as described above.

In yet another alternative embodiment of the invention, the formation of a device structure formed of Group III-V nitride material is illustrated in FIGS. 17-19. Referring to FIG. 17, a monocrystalline substrate 300, such as silicon (100), functions as the starting material. An accommodating buffer layer 302 is then grown epitaxially over substrate 300 and an amorphous intermediate layer 304 may be formed between substrate 300 and buffer layer 302 by the oxidation of substrate 300 during the growth of buffer layer 302. Buffer layer 302 may be comprised of a monocrystalline oxide or nitride material such as that comprising layer 24, 54 and 104 with reference to FIGS. 1, 9, and 11, respectively. Preferably, buffer layer 302 is comprised of SrTiO₃ epitaxially grown on substrate 300. A dielectric material is then lithographically deposited over buffer layer 302 to form patterned features 306 for subsequent ELO processing. Patterned features 306 may be comprised of any suitable dielectric material but is preferably comprised of SiO₂ or SiNₓ.

Referring to FIG. 18, a layer 308 of GaAs, preferably with a thickness of several monolayers, is deposited with growth conditions that cause the GaAs to migrate from the patterned features 306 into wells between patterned features 306. The GaAs layer is then subjected to nitridation to form GaN layer 308. As shown in FIG. 19, a III-V nitride film 310 is then epitaxially grown over patterned features 306 and GaN layer 308. Film 310 grows vertically to fill the wells between patterned features 306 and then grows laterally over patterned features 306. As with the above-described embodiments, with this growth process, defect density is reduced, as vertical-through dislocations do not propagate in the lateral direction, thereby creating a film that is smooth uniform film.

By fabricating Group III-V nitride films on compliant substrates using epitaxial lateral overgrowth as described above, electrical and optical devices may be achieved which realize a number of advantages. Use of a compliant substrate in the devices reduce stress due to lattice mismatch between the substrate and the III-V films. Thermal conductivity between layers is also improved. Further, epitaxial overgrowth acts to reduce dislocation density in the III-V films.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, solution to occur or become more pronounced are not to be constructed as critical, required, or essential features or elements of any or all of the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
a buffer layer formed on the substrate;
a first monocrystalline material layer formed overlying the buffer layer;
a plurality of patterned features formed of a dielectric material overlying the monocrystalline material layer;
a seed layer disposed between the plurality of patterned features; and
a second monocrystalline layer formed of III-V nitride material overlying the seed layer and the plurality of patterned features.

2. The semiconductor structure of claim 1, further comprising an amorphous oxide layer underlying the buffer layer.

3. The semiconductor structure of claim 1, wherein the substrate comprises silicon.

4. The semiconductor structure of claim 1, wherein the buffer layer comprises an oxide selected from the group consisting of alkali earth metal titanates, alkali earth metal zirconates, alkali earth metal hafnates, alkali earth metal tantalates, alkali earth metal ruthenates, alkali earth metal niobates, and perovskite oxides.

5. The semiconductor structure of claim 1, wherein the buffer layer is formed of material selected from the group comprising SrTiO₃, Sr_{z}Ba_{1-z}TiO₃, BaTiO₃, and CaTiO₃, where z ranges from approximately 0 to 1.

6. The semiconductor structure of claim 1, wherein the first monocrystalline material layer is formed of material selected from the group comprising GaAs, AlGaAs, InP, InGaAs, InGaP, ZnSe, ZnSeS and Si.

7. The semiconductor structure of claim 1, wherein the plurality of patterned features is formed of material selected from the group comprising SiQ₂ and SiNₓ, where x ranges from approximately 0 to 1.

8. The semiconductor structure of claim 1, wherein the plurality of patterned features are lithographically deposited.

9. The semiconductor structure of claim 6, wherein, when the first monocrystalline material layer comprises GaAs, the seed layer comprises GaN.

10. The semiconductor structure of claim 6, wherein the seed layer comprises SiC.

11. The semiconductor structure of claim 9, wherein the seed layer is formed by nitridation of a GaAs layer deposited overlying the first monocrystalline material layer.

12. The semiconductor structure of claim 10, wherein the seed layer is formed by carbonization of a Si layer deposited overlying the first monocrystalline material layer.

13. The semiconductor structure of claim 9, wherein the seed layer is formed by nitridation of the first monocrystalline material layer.

14. The semiconductor structure of claim 1, further comprising a template layer positioned between the buffer layer and the first monocrystalline material layer.

15. The semiconductor structure of claim 14, wherein the template layer is formed of material selected from the group comprising Ti—As, Sr—O—As, Sr—Ga—O, Ti—O—As, or Sr—Al—O.

16. The semiconductor structure of claim 14, wherein the template layer comprises a Zintl-type phase material.

17. The semiconductor structure of claim 16, wherein the Zintl-type phase material comprises at least one of SrAl₂, (MgCaYb)Ga₂, (Ca, Sr, Eu, Yb)In₂, BaGe₂As, and SrSn₂As₂.

18. The semiconductor structure of claim 14, wherein the template layer comprises a surfactant material.

19. The semiconductor structure of claim 18, wherein the surfactant material comprises at least one of Al, In, and Ga.

20. The semiconductor structure of claim 18, wherein the template layer further comprises a capping layer.

21. The semiconductor structure of claim 20, wherein the capping layer is formed by exposing the surfactant material to a cap-inducing material.

22. The semiconductor structure of claim 21, wherein the cap-inducing material comprises at least one of As, P, Sb, and N.

23. The semiconductor structure of claim 20, wherein the surfactant comprises Al, the capping layer comprises Al₂Sr and the second layer comprises GaAs.

24. The semiconductor structure of claim 1, wherein the second monocrystalline layer is formed by epitaxial lateral overgrowth processing.

25. A semiconductor structure comprising:
a monocrystalline substrate;
a buffer layer formed on the substrate;
a plurality of patterned features formed of a dielectric material overlying the buffer layer;
a seed layer disposed overlying the buffer layer and between the plurality of patterned features; and
a monocrystalline layer formed of III-V nitride material overlying seed layer and the plurality of patterned features.

26. The semiconductor structure of claim 25, further comprising an amorphous oxide layer underlying the buffer layer.

27. The semiconductor structure of claim 25, wherein the substrate comprises silicon.

28. The semiconductor structure of claim 25, wherein the buffer layer comprises an oxide selected from the group consisting of alkali earth metal titanates, alkali earth metal zirconates, alkali earth metal hafnates, alkali earth metal tantalates, alkali earth metal ruthinates, alkali earth metal niobates, and perovskite oxides.

29. The semiconductor structure of claim 25, wherein the buffer layer is formed of material selected from the group comprising SrTiO₃, Sr_{z}Ba_{1-z}TiO₃, BaTiO₃ and CaTiO₃.

30. The semiconductor structure of claim 25, wherein the plurality of patterned features is formed of material selected from the group comprising SiQ₂ and SiNₓ, where x ranges from approximately 0 to 1.

31. The semiconductor structure of claim 25, wherein the plurality of patterned features are lithographically deposited.

32. The semiconductor structure of claim 25, wherein the seed layer comprises GaN.

33. The semiconductor structure of claim 32, wherein the seed layer is formed by nitridation of a GaAs layer deposited between the patterned features and overlying the buffer layer.

34. The semiconductor structure of claim 25, wherein the monocrystalline layer is formed by epitaxial lateral overgrowth processing.

35. A process for fabricating a semiconductor structure comprising:
providing a monocrystalline substrate;
epitaxially growing an accommodating buffer layer overlying the substrate;
depositing a plurality of patterned features of a dielectric material overlying the accommodating buffer layer;
forming a seed layer disposed between the plurality of patterned features; and
epitaxially growing a first monocrystalline layer formed of III-V nitride material overlying the seed layer and the plurality of patterned features.

36. The process of claim 35, further comprising forming an amorphous oxide layer underlying the accommodating buffer layer during epitaxially growing the accommodating buffer layer.

37. The process of claim 35, wherein providing a monocrystalline substrate comprises providing a substrate formed of silicon.

38. The process of claim 35, further comprising epitaxially growing a second monocrystalline material layer overlying the accommodating buffer layer and underlying the plurality of patterned features.

39. The process of claim 38, wherein epitaxially growing a second monocrystalline material layer comprises epitaxially growing a monocrystalline oxide layer formed of an oxide selected from the group comprising alkali earth metal titanates, alkali earth metal zirconates, alkali earth metal hafnates, alkali earth metal tantalates, alkali earth metal ruthenates, alkali earth metal niobates and perovskite oxides.

40. The process of claim 35, wherein each of the steps of epitaxially growing comprises epitaxially growing by a process selected from the group consisting of MBE, MOCVD, MEE, CVD, PVD, PLD, CSD, and ALE.

41. The process of claim 35, wherein epitaxially growing an accommodating buffer layer comprises epitaxially growing a monocrystalline layer formed of material selected from the group comprising SrTiO₃, Sr_{z}Ba_{1-z}TiO₃, BaTiO₃, and CaTiO₃.

42. The process of claim 38, wherein epitaxially growing a second monocrystalline material layer comprises epitaxially growing a monocrystalline layer formed of material selected from the group comprising GaAs, AlGaAs, InP, InGaAs, InGaP, ZnSe, ZnSeS and Si.

43. The process of claim 35, wherein depositing a plurality of patterned features comprises depositing a plurality of patterned features formed of material selected from the group comprising SiO₂ and SiNₓ, where x ranges from 0 to 1.

44. The process of claim 35, wherein depositing a plurality of patterned features comprises lithographically depositing a plurality of patterned features.

45. The process of claim 35, wherein forming a seed layer comprises depositing a layer of GaAs and subsequently nitriding the layer of GaAs.

46. The process of claim 35, wherein forming a seed layer comprises depositing a layer of Si and subsequently carbonizing the layer of Si.

47. The process of claim 38, wherein forming the seed layer comprises nitriding the second monocrystalline material layer between the patterned features.

48. The process of claim 38, further comprising forming a template layer positioned between the accommodating buffer layer and the second monocrystalline material layer.

49. The process of claim 35, wherein epitaxially growing a first monocrystalline layer comprises growing the first monocrystalline layer by epitaxial lateral overgrowth processing.
